(19) United States
(12) Patent Application Publication
(10) Pub. No.: US 2014/0127911 A1
(43) Pub. Date: May 8, 2014

(54) PALLADIUM PLATED ALUMINUM COMPONENT OF A PLASMA PROCESSING CHAMBER AND METHOD OF MANUFACTURE THEREOF

(71) Applicant: LAM RESEARCH CORPORATION, Fremont, CA (US)

(72) Inventors: Hong Shih, Walnut, CA (US); Lin Xu, Katy, TX (US); Rajinder Dhindsa, San Jose, CA (US); Travis Taylor, Fremont, CA (US); John Daugherty, Fremont, CA (US)

(73) Assignee: LAM RESEARCH CORPORATION, Fremont, CA (US)

(21) Appl. No.: 13/670,940

(22) Filed: Nov. 7, 2012

(51) Int. Cl. H01L 21/67; H01L 21/02; H01L 21/3065; C25D 7/04; C25D 7/00

(52) U.S. Cl. CPC H01L 21/67017; H01L 21/67069; C25D 7/04; C25D 7/00; H01L 21/3065; H01L 21/02271
USPC 438/710; 156/345.48; 156/345.34; 118/723 I; 428/652; 428/629; 205/265; 205/151; 205/153; 438/758

(57) ABSTRACT

A palladium plated aluminum component of a semiconductor plasma processing chamber comprises a substrate including at least an aluminum or aluminum alloy surface, and a palladium plating on the aluminum or aluminum alloy surface of the substrate. The palladium plating comprises an exposed surface of the component and/or a mating surface of the component.

### FIELD OF THE INVENTION

The present invention relates to components of semiconductor plasma processing chambers.

### BACKGROUND

In the field of semiconductor material processing, semiconductor plasma processing chambers including vacuum processing chambers are used, for example, for etching and deposition, such as plasma etching or plasma enhanced chemical vapor deposition (PECVD) of various materials on substrates. Some of these processes utilize corrosive and erosive process gases and plasma in such processing chambers. It is desirable to minimize particle and/or metal contamination of substrates processed in the chambers. Accordingly, it is desirable that plasma-exposed components of such apparatuses be resistant to corrosion when exposed to such gases and plasma.

### SUMMARY

Disclosed herein is a palladium plated aluminum component of a semiconductor plasma processing chamber. The component comprises at least one aluminum or aluminum alloy surface coated with an electrically conductive and corrosion resistant palladium plating wherein the palladium plating comprises by weight at least about 95% palladium and up to about 5% other elements. The palladium plating comprises an exposed surface of the component and/or a mating surface of the component.

Also disclosed is a process for plating palladium on at least one aluminum or aluminum alloy surface of a component of a semiconductor plasma processing chamber. The process comprises electrodepositing an electrically conductive and corrosion resistant palladium plating comprising by weight at least about 95% palladium and up to about 5% other elements on the at least one aluminum or aluminum alloy surface.

Further disclosed herein is a semiconductor plasma processing apparatus. The semiconductor plasma processing apparatus comprises a semiconductor plasma processing chamber and a process gas source in fluid communication with the plasma processing chamber for supplying a process gas into the plasma processing chamber. The semiconductor plasma processing chamber also comprises an RF energy source adapted to energize the process gas into the plasma state in the plasma processing chamber, and at least one palladium plated aluminum component in the plasma processing chamber, wherein the at least one palladium plated aluminum component is part of a showerhead electrode assembly.

Also disclosed herein is a method of plasma processing a semiconductor substrate in a semiconductor plasma processing chamber including at least one palladium plated aluminum component. The method comprises supplying the process gas from the process gas source into the plasma processing chamber, applying RF energy to the process gas using the RF energy source to generate plasma in the plasma processing chamber, and plasma processing the semiconductor substrate in the semiconductor plasma processing chamber. In a preferred embodiment, the plasma processing chamber is a plasma etching chamber and the plasma processing is plasma etching.

### BRIEF DESCRIPTION OF THE DRAWING FIGURES

FIG. 1 illustrates a cross section of a palladium plated aluminum component of a plasma processing chamber.

FIG. 2 illustrates an exemplary embodiment of a capacitively coupled plasma etching chamber in which embodiments of the palladium plated aluminum components can be installed.

FIG. 3 illustrates an embodiment of palladium plated aluminum components.

FIG. 4 illustrates an embodiment of palladium plated aluminum components.

### DETAILED DESCRIPTION

Disclosed herein is an electrically conductive and corrosion resistant palladium plated aluminum component of a semiconductor plasma processing chamber such as a plasma etching or deposition chamber (herein referred to as “plasma chamber”) of a semiconductor plasma processing apparatus. In the following description, numerous specific details are set forth in order to provide a thorough understanding of the present embodiments. It will be apparent, however, to one skilled in the art that the present embodiments may be practiced without some or all of these specific details. In other instances, well known process operations have not been described in detail in order not to unnecessarily obscure the present embodiments.

Components described herein comprise a substrate of aluminum and an electrically conductive and corrosion resistant palladium plating on at least one aluminum or aluminum alloy exposed surface and/or mating surface of the substrate. The exposed surface that may be plated can be a plasma exposed or process gas exposed surface such as an exterior surface, or an interior surface that defines a hole, cavity, or aperture. The palladium plating can be applied on one or more, or on all, exterior surfaces of the substrate. The palladium plating can also be applied on one or more, or on all, accessible interior surfaces of the substrate.

Components which include the electrically conductive and corrosion resistant palladium plating can be used in apparatuses for performing various processes including plasma etching of semiconductor substrates and deposition of materials (e.g., ALD, PECVD and the like) used for manufacturing various substrates including, e.g., semiconductor wafers, flat panel display substrates and the like. Depending on the type and construction of an apparatus, the component(s) having at least one aluminum or aluminum alloy exposed surface and/or mating surface to be palladium plated can be, e.g., chamber walls, chamber liners, baffles, gas distribution plates, gas distribution rings, chucking mechanisms (e.g., electrostatic chucks), edge rings and conductor rings for substrate supports, gas nozzles, fasteners in the lower electrode assembly, shrouds, confinement rings, gaskets, RF straps, electrically conductive connecting members, and the like. For example the components may comprise an aluminum or aluminum alloy surface wherein the surface is exposed to process gas and/or plasma and configured to form a contact with another component such that electrical current may pass through both components during plasma processing of a semiconductor wafer. The palladium plating may be applied to the exposed aluminum or aluminum alloy surface of the component such that the surface may exhibit corrosion resistance while maintaining electrical conductivity as well as thermal conductivity. The components can include one or more exterior and/or interior surfaces plated with the electrically conductive and corrosion resistant palladium plating. In some embodiments, the entire exterior surface of the component may be plated.

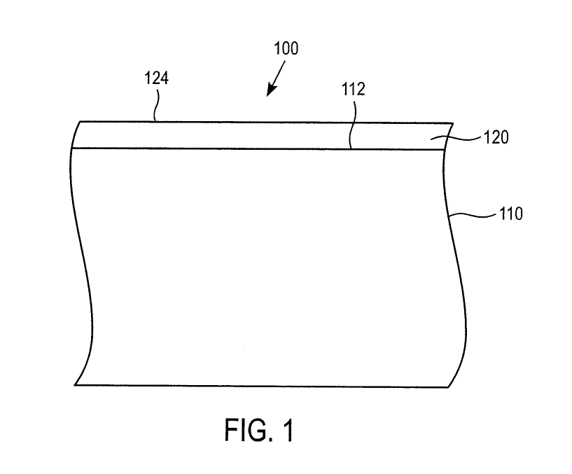

A palladium plated aluminum component 100 according to an exemplary embodiment is shown in FIG. 1. As shown, the component 100 comprises a substrate 110 including a surface 112 and an electrically conductive and corrosion resistant palladium plating 120 formed on the surface 112 such that it forms an outer surface 124 of the component 100. The substrate 110 may preferably be formed entirely of aluminum or an aluminum alloy (e.g., AL 6061), or alternatively may be formed from a composite of a conductive material, a dielectric material, or an insulator wherein the substrate 110 has at least one exposed surface 112 formed from aluminum or an aluminum alloy. If entirely of aluminum or an aluminum alloy, the substrate 110 can be wrought or cast aluminum. Preferably, the surface 112 of the substrate 110 to be plated is bare (non-anodized) aluminum. In alternative embodiments, the aluminum surface may be anodized and/or roughened.

The palladium layer 120 is preferably formed by electroplating palladium onto the at least one aluminum or aluminum alloy surface 112 of the substrate 110. The electroplating process can be used to form the electrically conductive and corrosion resistant palladium plating on external and/or internal surfaces that are difficult to access by other coating techniques, such as thermal spray techniques. Accordingly, by using electroplating processes to form the electrically conductive and corrosion resistant palladium plating, an enhanced number of parts and different part configurations can have the palladium plating. In an alternate embodiment the palladium plating may be applied by electroless plating.

The palladium plating forming the electrically conductive and corrosion resistant layer 120 can have a thickness of about 1 micrometer to about 100 micrometers, such as about 2 micrometers to about 15 micrometers. Preferably, the thickness of the palladium plating is substantially uniform over the surface 112 of the substrate 110. The palladium plating preferably contains at least about 95% by weight of palladium and up to about 5% by weight of other elements. Preferably, the palladium plating has a purity of at least about 99% by weight of palladium and up to about 1% by weight of incidental impurities. Most preferably, the palladium plating is comprised of at least 99.99% by weight of palladium.

The palladium plating is preferably very dense with less than about 1% by volume porosity, such as a porosity of less than about 0.5%, 0.1%, or 0.01%, i.e., has a density that approaches the theoretical density of the palladium. The palladium plating is preferably also free of defects. A low porosity level can minimize contact of aggressive plasma etch (e.g., plasma formed from fluorocarbon, fluorohydrocarbon, bromine, and chlorine containing etch gases) atmospheres with the underlying substrate. Accordingly, the palladium plating protects against physical and/or chemical attack of the substrate by such aggressive atmospheres.

The palladium plating forming the electrically conductive and corrosion resistant layer 120 preferably has good adhesion strength to the surfaces 112 of the substrate 110. The palladium plating can be formed directly on the substrate 110 without having previously roughened the substrate surface 112. In an alternate embodiment the substrate surface 112 may be roughened before the palladium plating is applied. In a preferred embodiment, the palladium plating provides suitable adherence without prior roughening of the substrate surface 112, which obviates additional process steps. Preferably, the palladium plating has a sufficiently-high adhesive bond strength to the surface(s) 112 of a substrate 110 on which the plating is formed such that when a tensile bond strength test is performed on the substrate 110, the palladium plating fails cohesively (i.e., in the substrate bulk) and not adhesively (i.e., at the substrate/plating interface).

In order to ensure good adhesion of the electroplated palladium plating to the substrate 110, the substrate surface 112 should be thoroughly cleaned from oxide scale and/or grease, prior to electroplating. This cleaning can be carried out by agitating the substrate 110 in a solution of dilute hydrochloric acid, or sulfuric acid, or in a degreasing solvent.

The palladium electroplating may be carried out by immersing the at least one aluminum or aluminum alloy surface 112 of the substrate 110 into a suitable electrolyte solution. The electroplating solution may contain additives for improving conductivity or for buffering the solution. An example of a palladium containing electroplating solution may be found in U.S. Pat. No. 4,911,798 which is incorporated by reference herein.

Embodiments of the palladium plated aluminum component may be used in plasma etch chambers or deposition chambers of semiconductor plasma processing apparatuses, such as capacitively coupled plasma etching chambers, inductively coupled plasma etching chambers, PECVD (plasma enhanced chemical vapor deposition) chambers, and ALD (atomic layer deposition) chambers for example. In these chambers, substrate surfaces can be exposed to plasma and/or process gases. In certain etching processes, these process gases can be halogen-containing species, e.g., CₓF_{y}, CₓH_{y}F_{z}, HBr, NF₃, HBr, Cl₂, and BCl₃, which are corrosive with respect to aluminum and aluminum alloy surfaces. The palladium plating, however, can be used to coat the plasma-exposed and/or process gas exposed aluminum or aluminum alloy surfaces to provide corrosion resistance from the plasma and process gases. Preferably the plasma-exposed and/or process gas exposed aluminum or aluminum alloy surfaces in the plasma processing apparatus are palladium plated and portions of the plated surfaces can form contact surfaces wherein electrical current may be conducted therethrough. The palladium plating may provide corrosion resistance to the exposed surfaces while not inhibiting electrical conduction or interfering with an RF return path provided by the component in a semiconductor plasma processing apparatus.

Although the palladium plating is applicable to any type of component having an aluminum or aluminum alloy surface, for ease of illustration, the plating will be described in more detail with reference to the apparatus described in commonly-assigned U.S. Published Application No. 2009/0200269 which is incorporated herein by reference in its entirety.

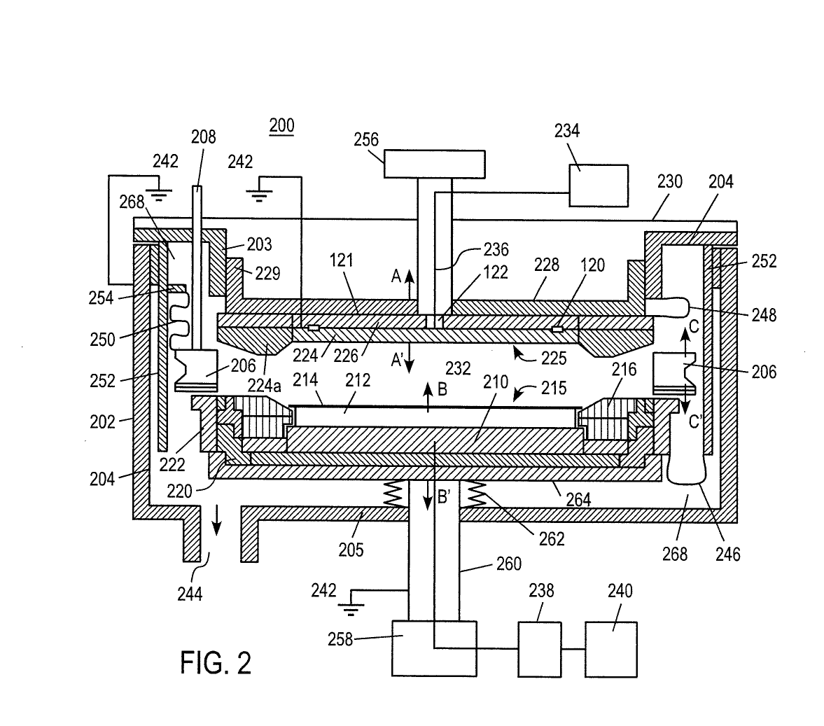

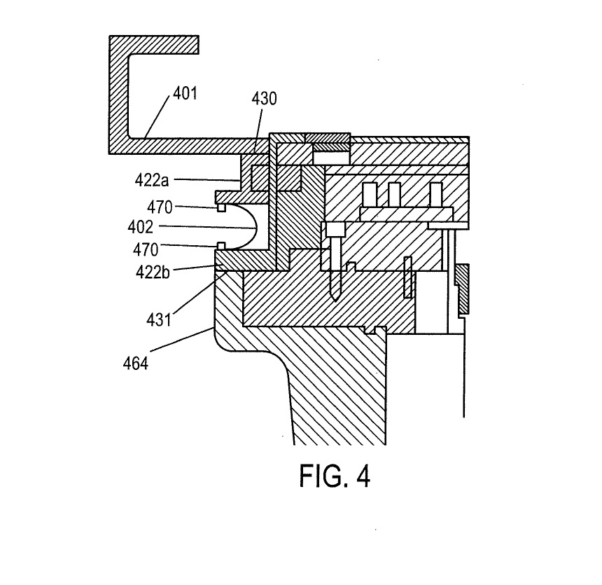

FIG. 2 shows an exemplary embodiment of an adjustable gap capacitively-coupled plasma (CCP) etching chamber 200 (“chamber”) of a plasma processing apparatus. The chamber 200 comprises chamber housing 202; an upper electrode assembly 225 mounted to a ceiling 228 of the chamber housing 202; a lower electrode assembly 215 mounted to a floor 205 of the chamber housing 202, spaced apart from and substantially parallel to the lower surface of the upper electrode assembly 225; a confinement ring assembly 206 surrounding a gap 232 between the upper electrode assembly 225 and the lower electrode assembly 215; an upper chamber wall 204; and a chamber top 230 enclosing the top portion of the upper electrode assembly 225. In an alternative embodiment, an annular shroud 401 (see FIG. 4) may replace the confinement ring assembly 206 such that the annular shroud 401 surrounds the gap 232 between the upper electrode assembly 225 and the lower electrode assembly 215.

The upper electrode assembly 225 may preferably comprise an upper showerhead electrode 224 and a gas distribution plate 226. The upper electrode assembly 225 may also optionally comprise an outer electrode 224a surrounding the upper showerhead electrode 224 as well as an optional gas distribution ring 226a surrounding the gas distribution plate 226. The upper showerhead electrode 224 and gas distribution plate 226 include gas passages for distributing process gas into the gap 232 defined between the upper showerhead electrode 224 and the lower electrode assembly 215. The upper electrode assembly 225 may further optionally comprise a gas distribution system such as one or more baffles (not shown) including gas passages for distributing process gas into the gap 232 defined between the upper showerhead electrode 224 and the lower electrode assembly 215. The upper electrode assembly 225 can include additional components such as RF gasket 120, a heating element 121, gas nozzle 122, and other parts. The chamber housing 202 has a gate (not shown) through which a substrate 214, is unloaded/loaded into the chamber 200. For example, the substrate 214 can enter the chamber through a load lock as described in commonly-assigned U.S. Pat. No. 6,899,109, which is hereby incorporated by reference in its entirety.

The upper showerhead electrode 224 is preferably formed from a semiconductor compatible material such as single crystal silicon or polysilicon. The gas distribution plate is preferably formed from aluminum or an aluminum alloy. Preferably, the gas distribution plate 226 and showerhead electrode 224 are configured such that they may conduct heat and direct RF current therethrough. Aluminum or aluminum alloy contact surfaces on the gas distribution plate 226 which interface with the silicon upper showerhead electrode may preferably be coated with the palladium plating to provide a palladium plated aluminum component. Additionally, a substrate such as an aluminum foil RF gasket 120 may also be plated with the palladium plating such as to form a corrosion resistant and electrically conductive palladium plated aluminum component which may conduct heat as well.

In some exemplary embodiments, the upper electrode assembly 225 is adjustable in up and down directions (arrows A and A′ in FIG. 2) to adjust the gap 232 between the upper and lower electrode assemblies 225/215. An upper assembly lift actuator 256 raises or lowers the upper electrode assembly 225. In the illustration, annular extension 229 extending vertically from the chamber ceiling 228 is adjustably positioned along cylindrical bore 203 of the upper chamber wall 204. A sealing arrangement (not shown) may be used to provide a vacuum seal between 229/203, while allowing the upper electrode assembly 225 to move relative to the upper chamber wall 204 and lower electrode assembly 215. A RF return strap 248 electrically couples the upper electrode assembly 225 and the upper chamber wall 204 such that direct current may be conducted therethrough.

The RF return strap 248 provides a conductive RF return path between the upper electrode assembly 225 and the upper chamber wall 204 to allow the electrode assembly 225 to move vertically within the chamber 200. The strap includes two planar ends connected by a curved section. The curved section accommodates movement of the upper electrode assembly 225 relative to the upper chamber wall 204. Depending on factors such as the chamber size, a plurality (2, 4, 6, 8, 10 or more) RF return straps 248 can be arranged at circumferentially spaced positions around the upper electrode assembly 225. Additionally, a plurality (2, 4, 6, 8, 10 or more) RF return straps 246 can be arranged at circumferentially spaced positions around the lower electrode assembly 215

For brevity, only one gas line 236 connected to gas source 234 is shown in FIG. 2. Additional gas lines can be coupled to the upper electrode assembly 225, and the gas can be supplied through other portions of the upper chamber wall 204 and/or the chamber top 230.

In other exemplary embodiments, the lower electrode assembly 215 may move up and down (arrows B and B′ in FIG. 2) to adjust the gap 232, while the upper electrode assembly 225 may be stationary or movable. FIG. 2 illustrates a lower assembly lift actuator 258 connected to a shaft 260 extending through the floor (bottom wall) 205 of the chamber housing 202 to a lower conducting member 264 supporting the lower electrode assembly 215. According to the embodiment illustrated in FIG. 1, a bellows 262 forms part of a sealing arrangement to provide a vacuum seal between the shaft 260 and the floor 205 of the chamber housing 202, while allowing the lower electrode assembly 215 to move relative to the upper chamber wall 204 and upper electrode assembly 225 when the shaft 260 is raised and lowered by the lower assembly lift actuator 258. If desired, the lower electrode assembly 215 can be raised and lowered by other arrangements. For example, another embodiment of an adjustable gap capacitively coupled plasma processing chamber which raises and lowers the lower electrode assembly 215 by a cantilever beam is disclosed in commonly-assigned U.S. Pat. No. 7,732,728, which is hereby incorporated by reference in its entirety.

If desired, the movable lower electrode assembly 215 can be grounded to a wall of the chamber by at least one lower RF strap 246 which electrically couples an outer conductor ring (ground ring) 222 to an electrically conductive part, such as a chamber wall liner 252 and provides a short RF return path for plasma, while allowing the lower electrode assembly 215 to move vertically within the chamber 200 such as during multistep plasma processing wherein the gap is set to different heights.

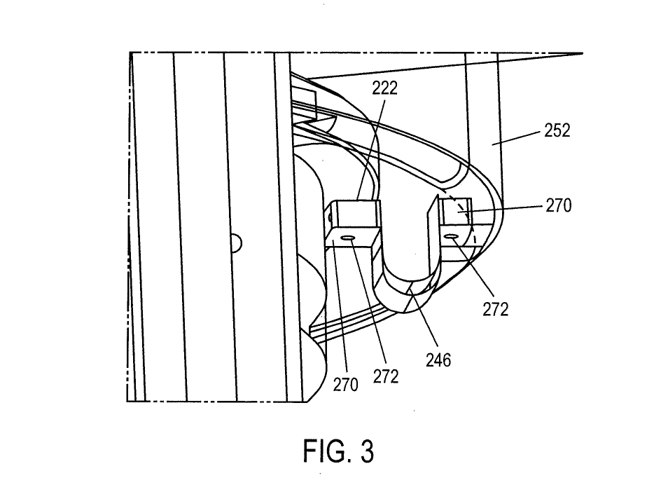

FIG. 3 illustrates an embodiment of a flexible and conductive RF strap 246 electrically connecting the outer conductor ring 222 to an electrically conductive chamber sidewall liner 252 in an adjustable gap capacitively-coupled plasma etching chamber 200. Electrically conductive connecting members 270 may be formed from aluminum or aluminum alloy metal blocks or aluminum or aluminum alloy plated metal blocks, wherein a first electrically conductive connecting member 270 connects a first end of the RF strap 246 to the electrically conductive chamber sidewall liner 252 and a second electrically conductive connecting member 270 connects a second end of the RF strap 246 to the outer conductor ring 222 such that heat and electricity may be conducted therethrough. The electrically conductive connective members 270, the RF strap 246, the outer conductor ring 222, and the electrically conductive chamber sidewall liner 252 may each comprise the palladium plating on plasma-exposed and/or process gas exposed aluminum or aluminum alloy surfaces as well as their respective mating surfaces. Preferably plasma-exposed and/or process gas exposed aluminum or aluminum alloy surface areas comprise the palladium plating such that the mating surfaces between the connecting members 270 and/or the flexible RF strap 246 as well as aluminum or aluminum alloy surface areas adjacent to the mating surfaces are protected from radicals by the palladium plating while maintaining high thermal and electrical conductivity such that electrical current may be conducted therethrough. Fastener holes 272 may be provided in the connecting members 270 adapted to accept fasteners such as screws, rivets, pins, and the like to complete the connections between the connecting members 270 and the RF strap 246. The fasteners may be formed from aluminum or an aluminum alloy or alternatively may be aluminum or aluminum alloy plated fasteners. To protect the fasteners from exposure to the oxygen and/or fluorine radicals, the palladium plating can also be provided on plasma-exposed and/or process gas exposed surfaces of the aluminum fasteners.

In the embodiment shown in FIG. 2, the lower conducting member 264 is electrically connected to an outer conductor ring (ground ring) 222 which surrounds dielectric coupling ring 220 which electrically insulates the outer conductor ring 222 from the lower electrode assembly 215. The lower electrode assembly 215 includes chuck 212, focus ring assembly 216, and a lower electrode 210. However, the lower electrode assembly 215 can include additional components, such as a lift pin mechanism for lifting the substrate, optical sensors, and a cooling mechanism for cooling the lower electrode assembly 215 attached to or forming portions of the lower electrode assembly 215. The chuck 212 clamps a substrate 214 in place on the top surface of the lower electrode assembly 215 during operation. The chuck 212 can be an electrostatic, vacuum, or mechanical chuck. Aluminum or aluminum alloy contact surfaces comprised in the lower electrode assembly 215 may preferably be palladium plated such that direct current may be conducted therethrough.

For example, as illustrated in FIG. 4, an annular shroud 401 is electrically connected to an outer conductor ring 422a at an interface 430 therebetween. The outer conductor ring 422a is electrically connected to a flexible and conductive RF strap 402 and the flexible and conductive RF strap 402 is electrically connected to an outer conductor ring 422b. Electrically conductive connecting members 470 may be formed from aluminum or aluminum alloy metal blocks or aluminum or aluminum alloy plated blocks, wherein a first electrically conductive connecting member 470 connects a first end of the RF strap 402 to the outer conductor ring 422a, and a second electrically conductive connecting member 470 connects a second end of the RF strap 402 to the outer conductor ring 422b such that electrical current may be conducted therethrough. The outer conductor ring 422b is electrically connected to a lower conducting member 464 at an interface 431 therebetween. The annular shroud 401, the outer conductor rings 422a, 422b, the flexible and conductive RF strap 402, and the electrically conductive aluminum or aluminum alloy blocks 470 may each comprise the palladium plating on plasma-exposed and/or process gas exposed aluminum or aluminum alloy surfaces as well as their respective mating surfaces. Preferably, contact surfaces at said interfaces 430, 431 are formed from aluminum or aluminum alloy and comprise the palladium plating.

Referring back to FIG. 2, the lower electrode 210 is typically supplied with RF power from one or more RF power supplies 240 coupled to the lower electrode 210 through an impedance matching network 238. The RF power can be supplied at one or more frequencies of, for example, 2 MHz, 13.56, 27 MHz, 400 KHz, and 60 MHz. The RF power excites the process gas to produce plasma in the gap 232. In some embodiments the upper showerhead electrode 224 and chamber housing 202 are electrically coupled to ground. In other embodiments the upper showerhead electrode 224 is insulated from the chamber housing 202 and supplied RF power from an RF supply through an impedance matching network.

The bottom of the upper chamber wall 204 is coupled to a vacuum pump unit 244 for exhausting gas from the chamber 200. Preferably, the confinement ring assembly 206 substantially terminates the electric fields formed within the gap 232 and prevents the electric fields from penetrating an outer chamber volume 268.

Process gas injected into the gap 232 is energized to produce plasma to process the substrate 214, passes through the confinement ring assembly 206, and into outer chamber volume 268 until exhausted by the vacuum pump unit 244. Since plasma chamber parts in the outer chamber volume 268 can be exposed to plasma and reactive process gas (radicals, active species) during operation, aluminum or aluminum alloys forming a surface of said chamber part may preferably comprise the electrically conductive and corrosion resistant palladium plating that can withstand the plasma and reactive process gas.

In an embodiment the RF power supply 240 supplies RF power to the lower electrode assembly 215 during operation, the RF power supply 240 delivers RF energy via shaft 260 to the lower electrode 210. The process gas in the gap 232 is electrically excited to produce plasma by the RF power delivered to the lower electrode 210.

Plasma chamber substrates, comprising at least one aluminum or aluminum alloy surface such as the gas distribution plate 226, gas distribution ring 226a, one or more optional baffles, aluminum or aluminum alloy surfaces comprised in the lower electrode assembly 215 such as the lower conducting member, the outer conductor rings, the annular shroud 401, and the chamber liner 252, chamber walls, aluminum foil RF gasket 120, electrically conductive connecting members 270, and fasteners may be palladium plated components. Any other substrate comprised in the semiconductor plasma processing apparatus having an aluminum or aluminum alloy surface, may also be palladium plated. Preferably, the palladium plating is applied to bare (nonanodized) aluminum surfaces of the aluminum components. The palladium plating can be coated on some or all of the exposed surfaces of the components. In an embodiment, the palladium plated aluminum components may have an outer palladium oxide layer.

While the invention has been described in detail with reference to specific embodiments thereof, it will be apparent to those skilled in the art that various changes and modifications can be made, and equivalents employed, without departing from the scope of the appended claims.

What is claimed is:

1. A palladium plated aluminum component of a semiconductor plasma processing chamber, the component comprising:
a substrate having at least one aluminum or aluminum alloy surface; and
an electrically conductive and corrosion resistant palladium plating comprising by weight at least about 95% palladium and up to about 5% other elements on the at least one aluminum or aluminum alloy surface of the substrate, wherein the palladium plating comprises an exposed surface of the component and/or a mating surface of the component.

2. The palladium plated component of claim 1, wherein the palladium plating is an electrodeposited layer comprising by weight at least about 99% palladium and up to 1% incidental impurities, and has a thickness of about 1 to 100 micrometers.

3. The palladium plated component of claim 1, wherein the palladium plating has a thickness of about 2 to 15 micrometers.

4. The palladium plated component of claim 1, wherein the palladium plating comprises by weight at least about 99.99% palladium.

5. The palladium plated component of claim 1, wherein the substrate is a gas distribution plate, a chamber wall, a chamber wall liner, baffle, gas distribution ring, chucking mechanism, conductor ring, fastener, the shroud, confinement ring, gasket, RF strap, or electrically conductive connecting member.

6. The palladium plated component of claim 1, wherein the palladium plating comprises an outer palladium oxide film.

7. The palladium plated component of claim 1, wherein the palladium plating is located on a portion of the component forming an electrical contact.

8. The palladium plated component of claim 1, wherein the palladium plating is located on a mating surface.

9. A process for palladium plating at least one aluminum or aluminum alloy surface of a component of a semiconductor plasma processing chamber, the process comprising:
electrodepositing an electrically conductive and corrosion resistant palladium plating comprising by weight at least about 95% palladium and up to about 5% other elements on the at least one aluminum or aluminum alloy surface of the component of the semiconductor plasma processing chamber.

10. The process of claim 9, wherein the component is a gas distribution plate, a chamber wall, a chamber wall liner, baffle, gas distribution ring, chucking mechanism, conductor ring, fastener, the shroud, confinement ring, gasket, RF strap, or electrically conductive connecting member.

11. A semiconductor plasma processing apparatus, comprising:
a plasma processing chamber in which semiconductor substrates are processed;
a process gas source in fluid communication with the plasma processing chamber for supplying a process gas into the plasma processing chamber;
an RF energy source adapted to energize the process gas into the plasma state in the plasma processing chamber;
and at least one palladium plated aluminum component according to claim 1 in the plasma processing chamber.

12. The semiconductor plasma processing chamber of claim 11, wherein the plasma processing chamber is a plasma etching chamber.

13. The semiconductor plasma processing chamber of claim 11, wherein the plasma processing chamber is a deposition chamber.

14. The semiconductor plasma processing chamber of claim 11, wherein the at least one palladium plated aluminum component is part of a showerhead electrode assembly.

15. A method of plasma processing a semiconductor substrate in the apparatus according to claim 11, comprising:
supplying the process gas from the process gas source into the plasma processing chamber;
applying RF energy to the process gas using the RF energy source to generate plasma in the plasma processing chamber; and
plasma processing a semiconductor substrate in the plasma processing chamber.

16. The method of claim 15, wherein the processing comprises plasma etching the substrate.

17. The method of claim 15, wherein the processing is a deposition process.
